(19) United States
(12) Patent Application Publication
(10) Pub. No.: US 2011/0186104 A1
(43) Pub. Date: Aug. 4, 2011

(54) SOLAR MODULE WINDOW SHADE APPARATUS AND METHOD

(75) Inventors: Daniel S. Shugar, San Bruno, CA (US); Kevin Gibson, Redwood City, CA (US)

(73) Assignee: Solaria Corporation, Fremont, CA (US)

(21) Appl. No.: 13/019,172

(22) Filed: Feb. 1, 2011

Related U.S. Application Data
(60) Provisional application No. 61/300,436, filed on Feb. 1, 2010.

(51) Int. Cl. H01L 31/042

(52) U.S. Cl. 136/244

(57) ABSTRACT

A solar module system includes a first transparent substrate member, a second transparent substrate member, and a plurality of photovoltaic members configured in a spatial manner sandwiched between the first substrate member and the second substrate member to allow at least a first portion of light to be transmitted and a second portion of light to be blocked. The system also has one or more inverter devices coupled to the solar module and configured to convert direct current to alternating current. The system may have an electrical cord comprising a first end and a second end, the first end being coupled to the one or more inverter devices and the second end comprising at least a pair of electrodes. The system can be used for indoor use or other application.

### CROSS-REFERENCES TO RELATED APPLICATIONS

This application claims priority to U.S. Provisional Patent Application No. 61/300,436 filed Feb. 1, 2010, which has been incorporated by reference for all purposes.

### BACKGROUND OF THE INVENTION

The present invention relates generally to solar energy techniques. In particular, the present invention provides a method and a structure for a resulting solar module. Merely by way of example, the invention has been applied to solar panels, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable. Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

The present invention relates generally to solar energy techniques. In particular, the present invention provides a method and a structure for a resulting solar module. By way of example, embodiments according to the present invention have been applied to solar panels but it would be recognized the present invention can have a broader range of applicability.

In a specific embodiment, the present invention provides a solar module system. The system has a solar module comprising a first transparent substrate member, a second transparent substrate member, and a plurality of photovoltaic members configured in a spatial manner sandwiched between the first substrate member and the second substrate member to allow at least a first portion of light to be transmitted and a second portion of light to be blocked. The system also has one or more inverter devices coupled to the solar module and configured to convert direct current to alternating current. In a preferred embodiment, the system has an electrical cord comprising a first end and a second end, the first end being coupled to the one or more inverter devices and the second end comprising at least a pair of electrodes. In one or more embodiments, the system can be used for indoor use or other application.

In an alternative specific embodiment, the present invention provides a solar module apparatus. The apparatus has a first transparent substrate member and a second transparent substrate member. The apparatus also has a plurality of photovoltaic members configured in a spatial manner sandwiched between the first substrate member and the second substrate member to allow at least a first portion of light to be transmitted and a second portion of light to be blocked.

Many benefits can be achieved by ways of the present invention. For example, the present solar module provide a simplified structure for manufacturing process and indoor use. In one or more embodiments, the present solar system can be configured for indoor use and is substantially transparent. The system can also be configured as a window shade or the like. The present solar module may be fabricated using few process steps resulting in lower cost and improved product reliability due to less mismatch in thermal expansion coefficients of the materials. These and other benefits may be described throughout the present specification and more particularly below. Additionally, further details of certain elements of the present method and apparatus can be found in co-owned application No. PCT/US2010/024943 filed Feb. 22, 2010, commonly assigned, and hereby incorporated by reference here.

### BRIEF DESCRIPTION OF THE DRAWINGS

FIG. 1 is a front view photograph of a solar shade according to an embodiment of the present invention.

FIG. 2 is a simplified system diagram of a solar shade apparatus according to an embodiment of the present invention.

FIGS. 3 through 7 are detailed descriptions of elements of the solar shade apparatus according to embodiments of the present invention.

### DETAILED DESCRIPTION OF THE INVENTION

According to embodiments of the present invention, a structure and a method for a solar module is provided. More particularly, embodiments according to the present invention provides a cost effective method and a structure for a solar module using concentrating elements. Merely by way of example, embodiments according to the present invention have been applied to solar panels but it would be recognized that embodiments according to the present invention have a broader range of applicability.

In a specific embodiment, the present solar module has one or more of the following features:

Produces electricity

Provides shading
Reduces air-conditioning (AC) costs

Eliminates issues regarding weatherability
Indoors behind a main window

Eliminates issues regarding being an integral part of the structure
Many BIPV modules are design to be the window as well
Must provide structural strength and 50+ year life
Electrical interconnects a major issue

Module does not have to fit to window frame size

Movable and detachable

Easy to install—can be do-it yourself (DIY) application

Free from expensive electrical wiring
Can be installed without an electrician, simply plug into a wall

Gap between window and module eliminates fogging.

Depending upon the embodiment, one or more of these features may be included. Of course, there can be other variations, modifications, and alternatives.

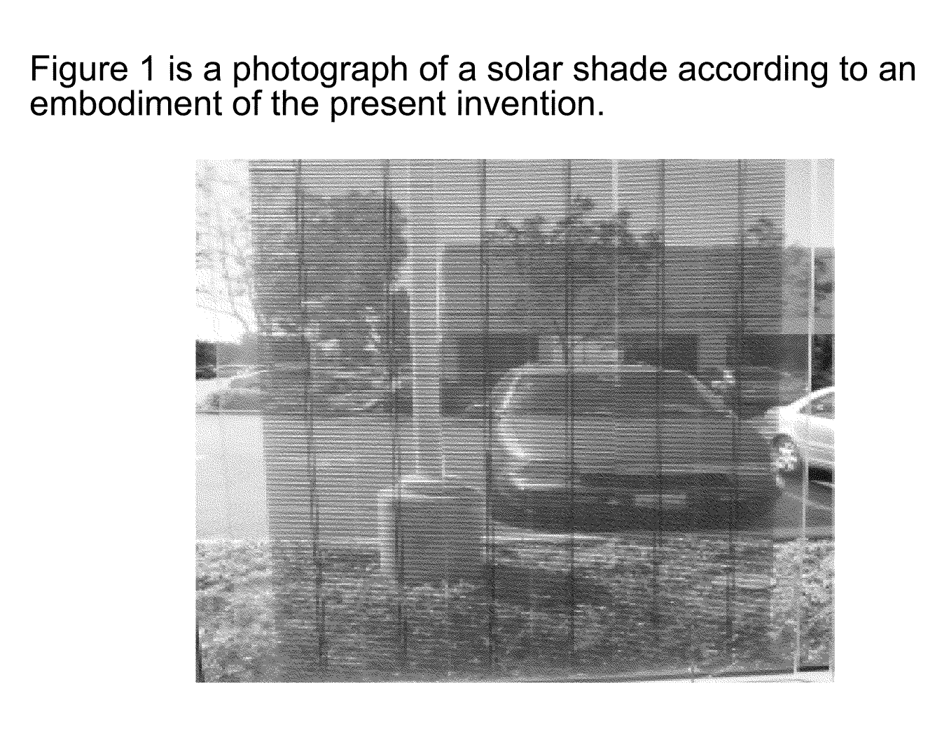

FIG. 1 is a front view photograph of a solar shade according to an embodiment of the present invention. This diagram is merely an example, which should not unduly limit the scope of the claims herein. One of ordinary skill in the art would recognize other variations, modifications, and alternatives. As shown, the solar shade includes, generally from back to front, the following elements: a back glass substrate member, a plurality of photovoltaic strips, a cover glass aligned and coupled to the photovoltaic strips by an optically clear adhesive, among other elements. The glass substrate member can be made of any suitable glass or a polymer material, and cover glass member can be made of glass or a transparent polymer material. Of course, there can be other variations, modifications, and alternatives.

In a specific embodiment, the present invention provides a solar module system. The system has a solar module comprising a first transparent substrate member, a second transparent substrate member, and a plurality of photovoltaic members configured in a spatial manner sandwiched between the first substrate member and the second substrate member to allow at least a first portion of light to be transmitted and a second portion of light to be blocked. Photovoltaic regions are preferably configured as strips, and can be silicon based, for example, monocrystalline silicon, polysilicon, or amorphous silicon material. That is, each strip is diced using a scribe and/or saw process from a conventional silicon base solar cell, which is functional. As an example, such conventional solar cell can be from SunPower Corporation, Suntech Power of the People's Republic of China, and others. Alternatively, the photovoltaic strip can be made of a thin film photovoltaic material. The thin film photovoltaic material may include CIS, CIGS, CdTe, and others. Each of the photovoltaic strips can have a width ranging from about 2 mm to about 10 mm, depending on the embodiment. In typical embodiments, the photovoltaic strips are cut from a wafer, but in other embodiments, the photovoltaic strips might be deposited on the substrate.

The system also has one or more inverter devices coupled to the solar module and configured to convert direct current to alternating current. An example of a solar inverter has been described at http://en.wikipedia.org/wiki/Solar_inverter as follows. “A solar inverter or PV inverter is a type of electrical inverter that is made to change the direct current (DC) electricity from a photovoltaic array into alternating current (AC) for use with home appliances and possibly a utility grid.” Of course, there can be other variations, modifications, and alternatives.

In a preferred embodiment, the system has an electrical cord comprising a first end and a second end, the first end being coupled to the one or more inverter devices and the second end comprising at least a pair of electrodes. In one or more embodiments, the system can be used for indoor use or other application. Of course, there can be other variations, alternatives, and modifications.

This type of construction can be subject to some limitations. For example, the different materials are typically characterized by different thermal expansion coefficients, which can lead to mechanical stresses that reduce product reliability. Of course, there can be other variations, modifications, and alternatives.

In a specific embodiment, the glass substrate or member can also include a coating or multiple coatings. The coating material can be selected to prevent dirt and other contaminants from building up on the surface. Saint-Gobain Glass markets what they refer to as “self-cleaning” glass, under the registered trademark SGG BIOCLEAN. An explanation on the Saint-Gobain Glass website describes the operation as follows: A transparent coating on the outside of the glass harnesses the power of both sun and rain to efficiently remove dirt and grime. Exposure to the UV rays present in daylight triggers the decomposition of organic dirt and prevents mineral dirt from adhering to the surface of the glass. It also turns it “hydrophilic” meaning that when it rains the water sheets across the glass, without forming droplets, rinsing away the broken down dirty residues. Only a small amount of sunlight is required to activate the coating so the self-cleaning function will work even on cloudy days. A simple rinse of water during dry spells will help keep windows clean. U.S. Pat. No. 6,846,556 to Boire et al. titled “Substrate with a Photocatalytic Coating” describes such a glass. The K2 Glass division of K2 Conservatories Ltd. also manufactures and markets what they refer to as the Easy Clean System, namely “a system for converting ordinary glass into ‘Non Stick’, easy to clean glass.”

Wikipedia provides a number of suppliers of self-cleaning glass as follows (citations omitted):
The Pilkington Activ brand by Pilkington is claimed by the company to be the first self-cleaning glass. It uses the 15 nm thick transparent coating of microcrystalline titanium dioxide. The coating is applied by chemical vapor deposition
The SunClean brand by PPG Industries also uses a coating of titanium dioxide, applied by a patented process.
Neat Glass by Cardinal Glass Industries has a titanium dioxide layer less than 10 nm thick applied by magnetron sputtering
SGG Aquaclean (1st generation, hydrophilic only, 2002) and Bioclean (2nd generation, both photoactive and hydrophilic, 2003) by Saint-Gobain. The Bioclean coating is applied by chemical vapor deposition.

A coating, such as those described above, can be combined with other coatings to enhance the performance of the solar module. For example, anti-reflective coatings can be used to increase the amount of light captured by the solar module. XeroCoat, Inc. of Redwood City, Calif. and its subsidiary XeroCoat Pty. Ltd. of Brisbane, Australia state that they are working on a grant from Australia's Climate Ready program to address solar efficiency loss due to accumulated dust and soil, as well as reflection.

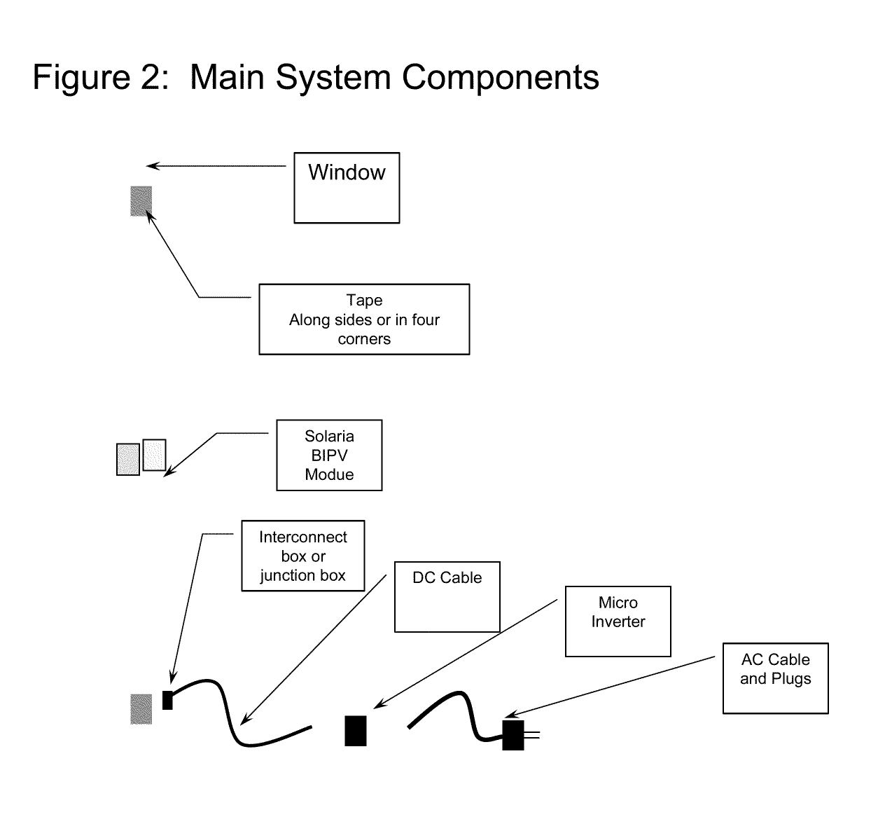

FIG. 2 is a simplified system diagram of a solar shade apparatus and the components according to an embodiment of the present invention. This diagram is merely an example, which should not unduly limit the scope of the claims herein. One of ordinary skill in the art would recognize other variations, modifications, and alternatives.

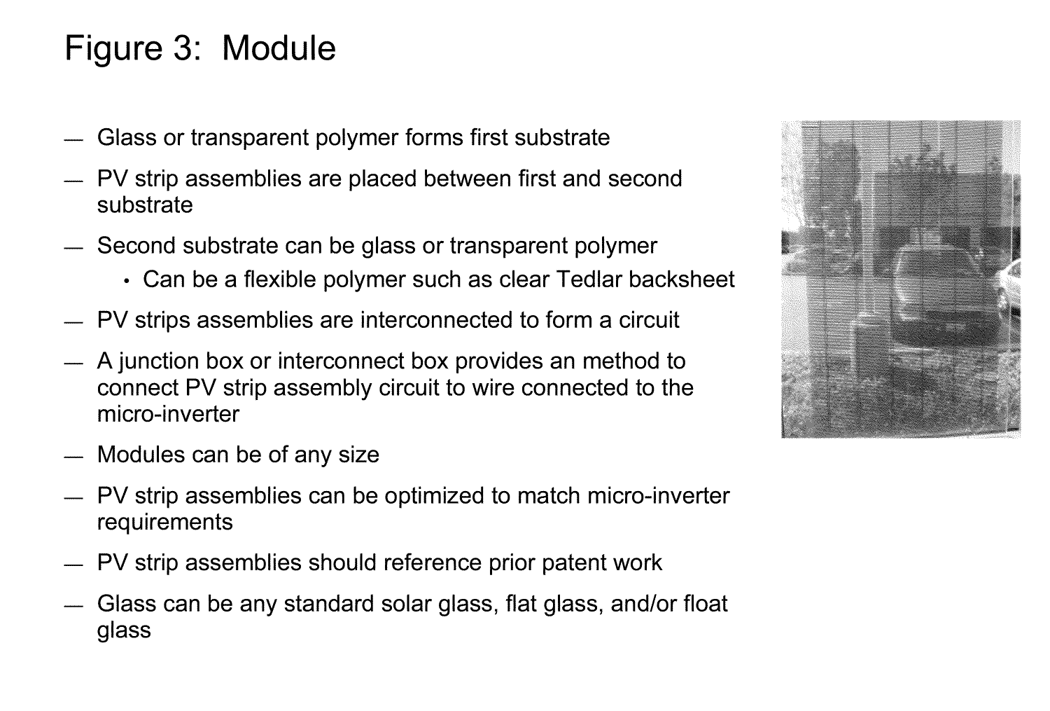

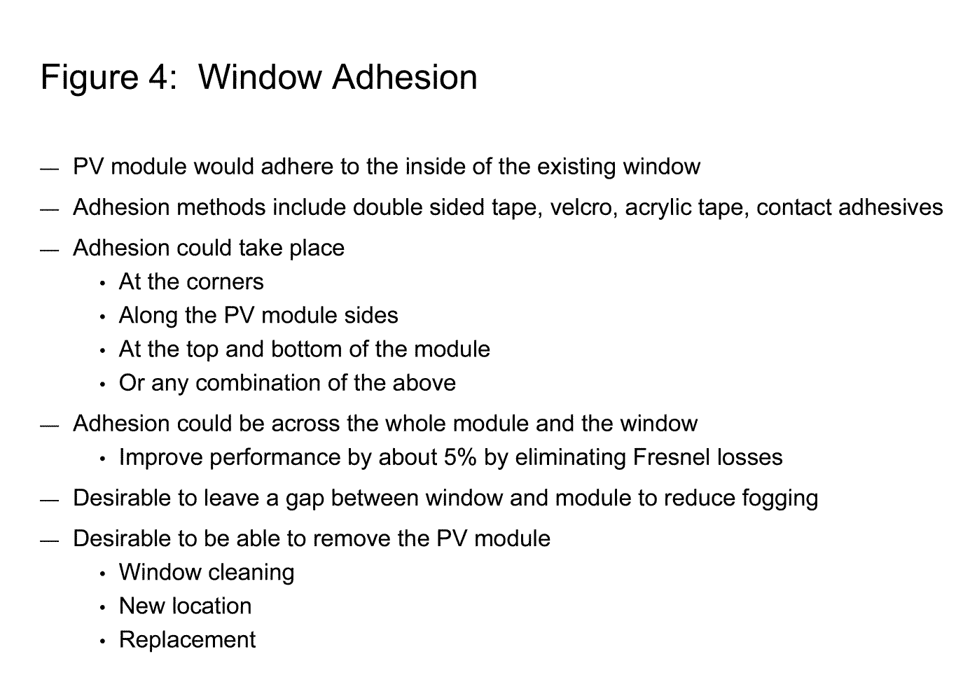

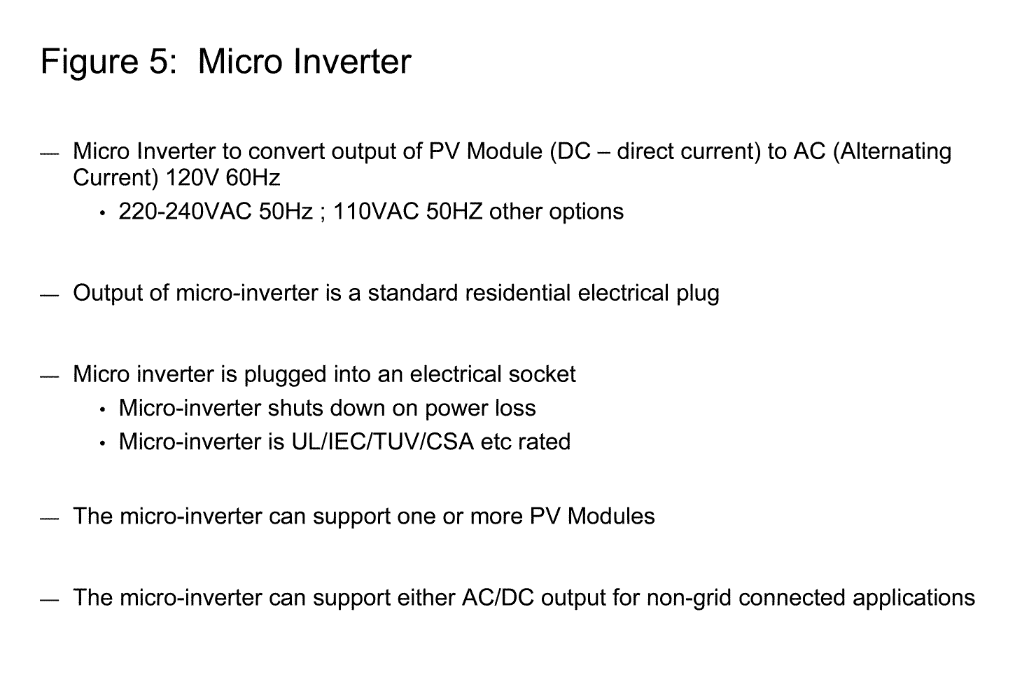

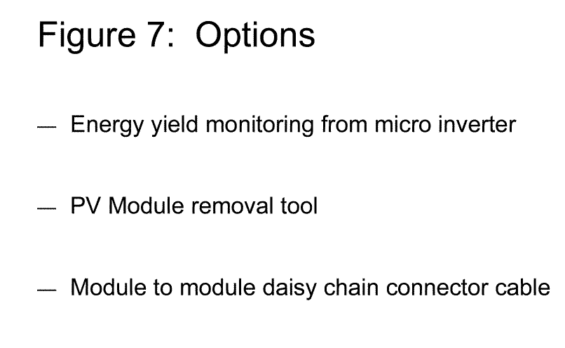

FIGS. 3 through 7 are detailed descriptions of elements of the solar shade apparatus according to embodiments of the present invention. These diagrams are merely examples, which should not unduly limit the scope of the claims herein. One of ordinary skill in the art would recognize other variations, modifications, and alternatives. In a specific embodiment, the solar module, which allows light to traverse through open regions, is comprised of a glass or transparent polymer (or combinations thereof) that forms a first substrate. In a specific embodiment, the glass can be a boron glass, soda lime glass, solar glass, float glass, white water glass, or others. In a specific embodiment, the first substrate includes a plurality of photovoltaic (PV) strip assemblies placed between the first and a second substrate, which can be made of a glass or transparent polymer, or combinations thereof. In a specific embodiment, one of both of the substrates can also be made of a flexible polymer such as clear Tedlar backsheet or the like. One of ordinary skill in the art would recognize other variations, modifications, and alternatives.

In a specific embodiment, the PV strips or assemblies are interconnected to form a circuit. The circuit forms a plurality of separate solar cells, each of which is one of the PV assemblies. In a specific embodiment, the photovoltaic strips are preferably configured from individual strips, and can be silicon based, for example, monocrystalline silicon, polysilicon, or amorphous silicon material. That is, each strip is diced using a scribe and/or saw process from a conventional silicon base solar cell, which is functional. As an example, such conventional solar cell can be from SunPower Corporation, Suntech Power of the People's Republic of China, and others. Alternatively, the photovoltaic strip can be made of a thin film photovoltaic material. The thin film photovoltaic material may include CIS, CIGS, CdTe, and others. Each of the photovoltaic strips can have a width ranging from about 2 mm to about 10 mm, depending on the embodiment. In typical embodiments, the photovoltaic strips are cut from a wafer, but in other embodiments, the photovoltaic strips might be deposited on the substrate. Of course, there can be other variations, modifications, and alternatives.

In a specific embodiment, the solar module has other features. The module has a first encapsulant material disposed between the surface region of the substrate and the one or more photovoltaic regions and a second encapsulant material disposed between the glass member and the one or more photovoltaic regions. In a specific embodiment, the encapsulant material includes EVA or other suitable material, which is transparent and has desirable mechanical and optical properties. Of course, there can be other variations, modifications, and alternatives.

In a preferred embodiment, the module couples to or adheres to the inside of an existing window in a house or other building structure. In a specific embodiment, the adhesion methods include double sided tape, velcro, acrylic tape, contact adhesives, or others. In a specific embodiment, adhesion may take place at corners of the module or along edges or sides of the modules. In a specific embodiment, adhesion may take place along the top or bottom of the module or any combination of these spatial regions of the module or the like. In a specific embodiment, the adhesion may also include regions across the whole module and the window. In a specific embodiment, the present module and/or system improves performance by about 5% by eliminating Fresnel losses or the like. In preferred embodiments, the module is configured to the window with a predetermined space gap between the window and the module to reduce fogging or other undesirable influences. In a specific embodiment, the module is also configured to be removed and cleaned. In a specific embodiment, the module is removed for window cleaning and can be placed at a new or separate location. In other embodiments, the module can also be replaced with another module. Of course, there can be other variations, modifications, and alternatives.

Also shown, the solar window includes a junction box or interconnect box. Preferably, the solar window also includes a wire connected to the micro-inverter. The wire or wires include leads that can plug into an electrical outline to provide power back to the power line network or the like. In other embodiments, the solar window includes one or more individual modules, which can be optimized by size and shape. In other embodiments, the solar modules and/or assemblies can be configured or optimized to match a micro-inverter requirement. Further details of the solar window can be found throughout the present specification and more particularly below.

In a specific embodiment, the window shade includes a micro inverter. Such micro inverter is configured to convert output of PV Module (DC—direct current) to AC (Alternating Current) 120V 60 Hz or other desirable voltage and frequency. In a specific embodiment, the other voltages can also include 220-240 VAC 50 Hz, 110 VAC 50 HZ, and other options. In a specific embodiment, the output of the micro-inverter is a standard residential electrical plug or the like. That is, the micro inverter is plugged into an electrical socket and preferably shuts down the when there is power loss or other event. In a preferred embodiment, the micro-invert is suitably rated, e.g., UL/IEC/TUV/CSA. In a specific embodiment, the micro-inverter can support one or more modules or window shades. In a specific embodiment, the micro-inverter can support either AC/DC output for non-grid connected applications. Of course, there can be other variations, modifications, and alternatives.

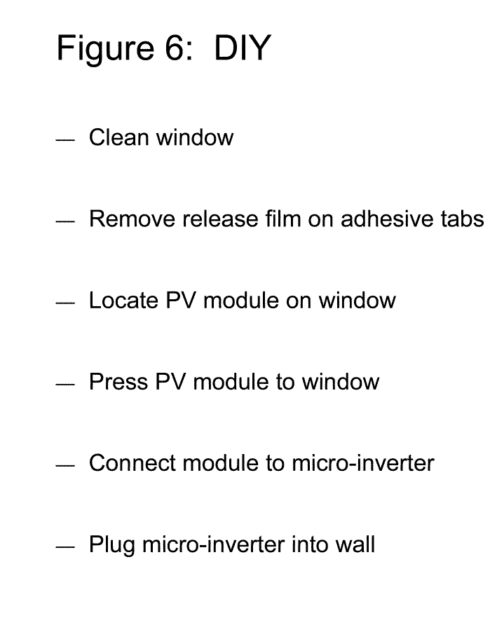

In a specific embodiment referring to FIG. 6 again, the present invention provides the following sequence of steps, which may be combined, separated, or other steps added, or removed.
1. Clean window on building;
2. Remove release film on adhesive tabs, which are configured to the window and/or module;
3. Position module to desired spatial region of the window;
4. Press module to window and cause adhesive tabs to adhere module to the window;
5. Allow module to settle on window, if necessary;
6. Connect module to micro-inverter;
7. Plug micro-inverter into power line network on the wall;
8. Allow electromagnetic radiation to contact module to generate electricity;
9. Convert electricity from DC to AC; and
10. Transmit AC to powerline network.

Of course, there can be other variations, modifications, and alternatives.

In a specific embodiment, the window shade module has other variations. That is, the module includes energy yield and/or usage monitoring from the micro inverter, which has been configured for such monitoring. In a specific embodiment, the module also includes a PV module removal tool, which allows a user to remove the module from the exterior window or other substrate. In a specific embodiment, the present system and method includes a module to module daisy chain connector cable to configure a plurality of modules together. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar module apparatus comprising:
a first transparent substrate member;
a second transparent substrate member; and
a plurality of photovoltaic members configured in a spatial manner sandwiched between the first substrate member and the second substrate member to allow at least a first portion of light to be transmitted and a second portion of light to be blocked; and
whereupon the plurality of photovoltaic members are configured to generate power, provide shade, and allow light to be transmitted.

2. The apparatus of claim 1 wherein the apparatus is provided within an interior region of a building structure.

3. The apparatus of claim 1 wherein the first transparent member, the plurality of photovoltaic members, and the second transparent substrate form a movable solar module.

4. The apparatus of claim 1 further comprising an inverter device configured with the plurality of photovoltaic members to convert direct current power to alternating current power.

5. The apparatus of claim 4 further comprising an electric cord coupled to the inverter device and having at least a pair of contact members to be connected to an interior electrical socket.

6. The apparatus of claim 1 wherein each of the plurality of photovoltaic members comprises at least a pair of electrodes.

7. The apparatus of claim 1 wherein each of the plurality of photovoltaic members comprises silicon material.

8. The apparatus of claim 1 wherein each of the plurality of photovoltaic members is coupled to the first transparent substrate member using one or more elastomeric materials.

9. The apparatus of claim 1 wherein the first transparent substrate comprises a glass.

10. The apparatus of claim 1 wherein the second transparent substrate comprises a glass.

11. A solar module system comprising:
a solar module comprising a first transparent substrate member, a second transparent substrate member, and a plurality of photovoltaic members configured in a spatial manner sandwiched between the first substrate member and the second substrate member to allow at least a first portion of light to be transmitted and a second portion of light to be blocked;
one or more inverter devices coupled to the solar module and configured to convert direct current to alternating current; and
an electrical cord comprising a first end and a second end, the first end being coupled to the one or more inverter devices and the second end comprising at least a pair of electrodes.

12. The apparatus of claim 11 wherein the apparatus is provided within an interior region of a building structure.

13. The apparatus of claim 11 wherein the first transparent member, the plurality of photovoltaic members, and the second transparent substrate form a movable solar module.

14. The apparatus of claim 11 wherein each of the plurality of photovoltaic members comprises at least a pair of electrodes.

15. The apparatus of claim 11 wherein each of the plurality of photovoltaic members comprises silicon material.

16. The apparatus of claim 11 wherein each of the plurality of photovoltaic members is coupled to the first transparent substrate member using one or more elastomeric materials.

17. The apparatus of claim 11 wherein the first transparent substrate comprises a glass.

18. The apparatus of claim 11 wherein the second transparent substrate comprises a glass.

19. The apparatus of claim 11 wherein the first transparent substrate is annular in shape

20. The apparatus of claim 11 wherein the second transparent substrate is annular in shape.
